(19) United States
(12) Patent Application Publication
(10) Pub. No.: US 2002/0197836 A1
(43) Pub. Date: Dec. 26, 2002

(54) Method of forming variable oxide thicknesses across semiconductor chips

(75) Inventors: S. Sundar Kumar Iyer, Beacon, NY (US); Suryanarayan G. Hegde, Hollowville, NY (US); Erin Catherine Jones, Tuckahoe, NY (US); Harald F. Okorn-Schmidt, Putnam Valley, NY (US)

Correspondence Address: Philmore H. Colburn II, Cantor Colburn LLP, 55 Griffin Road South, Bloomfield, CT, 06002, US

(73) Assignee: International Business Machines Corporation, Armonk, NY

(21) Appl. No.: 09/878,556

(22) Filed: Jun. 11, 2001

(51) Int. Cl. H01L 21/3205; H01L 21/336; H01L 21/4763

(52) U.S. Cl. 438/585; 438/279; 438/981

(57) ABSTRACT

A method for forming variable oxide thicknesses across semiconductor chips comprises providing a silicon semiconductor substrate having pre-selected areas open to silicon surface using a photoresist layer; immersing the silicon semiconductor substrate in an HF type electrolytic bath to produce a porous silicon area; and removing the photoresist layer and oxidizing the silicon semiconductor substrate to produce a plurality of thicknesses of gate oxide on the silicon semiconductor substrate.

### BACKGROUND OF THE INVENTION

The present invention relates to processes for the fabrication of integrated circuit devices on semiconductor substrates, and in particular to processes by which oxide dielectric layers featuring variable thicknesses are fabricated across a semiconductor substrate surface.

In producing DRAM integrated circuits, varying oxide thicknesses are required to be fabricated across the various regions of the semiconductor chip in order to be compatible with the different voltage requirements. Known thermal oxidation processes for fabricating these different gate oxide thicknesses on the same wafer typically involve removing the thick oxide from regions where a thin oxide is required, using, e.g., an etch process. Regions requiring thick oxide layers are thus typically masked with photoresist to prevent etching. Such conventional thermal oxidation methods include atmospheric pressure methods under dry oxygen or wet oxygen (i.e., employing a bubbler, flash system, dry oxidation) conditions, high pressure methods under dry or wet oxygen conditions, and anodic oxidation methods. However, these conventional methods require multiple steps that increase time, labor and costs pertaining to manufacturing and raw materials.

### BRIEF SUMMARY OF THE INVENTION

A method of forming oxide layers of varying thicknesses across a semiconductor substrate surface comprises patterning and blocking a semiconductor substrate surface with a layer of photoresist material; removing a portion of the photoresist material layer to expose a device isolated region on the blocked semiconductor substrate surface; increasing a differential oxidation rate value of the exposed semiconductor substrate surface; removing the layer of photoresist material; oxidizing the semiconductor substrate surface; forming a first oxide layer having a first thickness on the exposed semiconductor substrate surface; and forming a second oxide layer having a second thickness on the blocked semiconductor substrate surface, wherein the first thickness is greater than the second thickness.

### BRIEF DESCRIPTION OF THE DRAWINGS

The invention will be more fully understood in light of the following detailed description of taken together with the following drawings, which are illustrative, rather than limiting:

FIGS. 1-6 are sectional views illustrating the process steps of fabricating variable oxide thicknesses across a semiconductor chip.

### DETAILED DESCRIPTION OF THE INVENTION

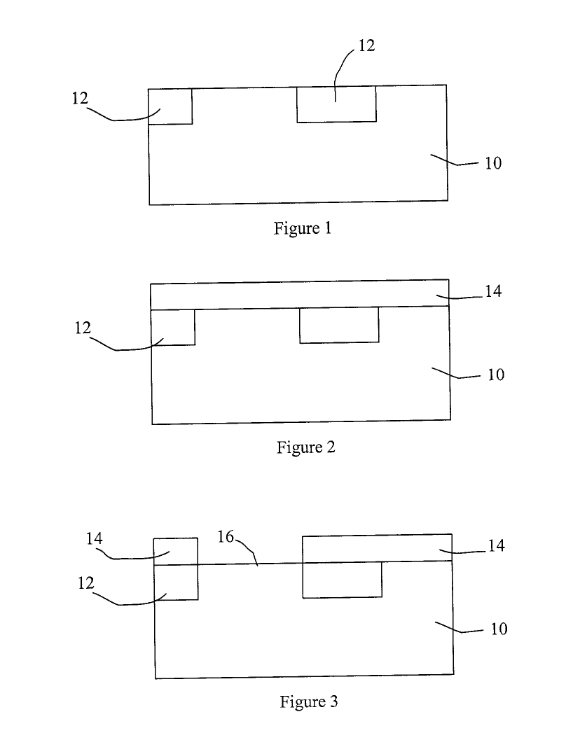

In accordance with the present method, FIG. 1 illustrates a semiconductor substrate 10 comprising one or more active area regions comprising one or more sharply defined trenches 12 formed using shallow trench isolation (“STI”). The shallow trench 12 can be filled with oxide back to the surface of the semiconductor substrate 10 to provide a device isolation region. Trench isolation regions formed by STI have the advantages of providing device isolation across their entire lateral extent and of providing a more planar structure. Possible semiconductor substrate materials comprise intrinsic semiconducting materials, i.e., materials having some natural electrical conducting ability, and/or materials having conductivity values between that of an electrical insulator material and an electrical conductor material, such as elemental semiconductors of column IVA of the periodic table, e.g., silicon and germanium, and compounds comprising at least one of the elements found in columns IIIA and VA, e.g., gallium arsenide and gallium phosphide, and/or columns IIIB and VIA, as well as combinations comprising at least one of the foregoing semiconductor substrate materials, and the like.

More particularly, the semiconductor substrate materials are doped with a doping material that increases the conductivity of the aforementioned intrinsic semiconductor materials. Possible doping materials can comprise N type dopant sources such as antimony trioxide, arsenic trioxide, and phosphorous pentoxide (solids); phosphorous oxychloride (liquid); and, arsine and phosphine (gases), or P type dopant sources such as boron trioxide and boron nitride (solids); boron tribromide (liquid); diborane and boron trichloride (gases). The doped semiconductor substrate 10 can also be doped a second time to form an N-P or P-N junction, or undergo same type doping so that a junction is not formed. The semiconductor substrate 10 can be doped one or more times using several methods such as diffusion processes, ion implantation processes, as well as combinations comprising at least one of the foregoing methods, and the like.

In FIG. 2, a layer of photoresist material 14 can be deposited over the semiconductor substrate 10. The choice of photoresist materials is based upon the dimensions required on the semiconductor substrate 10 surface, and other factors including, but not limited to, performance capabilities, functions, and physical properties such as resolution capability; adhesion capability; photoresist exposure speed, sensitivity and exposure source; pinholes; particle and contamination levels; step coverage; and thermal flow; as well as, solids content, viscosity, surface tension, index of refraction, storage and control of the photoresist material, light and heat sensitivity, viscosity sensitivity, and shelf life. More particularly, the photoresist materials can prevent the masked region from becoming porous while carrying out the disclosed process. Possible photoresist materials can comprise I-line 3250 resist materials manufactured by Tokyo Ohka Togyo Company Limited, based in Kawasaki, Japan; M20 series resist materials (e.g., M20G, M22G, and the like) manufactured by JSR Corporation, based in Tokyo, Japan; and, Deep Ultra-Violet resist material such as Uv82 manufactured by Shipley Company, L.L.C., based in Marlborough, Mass., as well as combinations comprising at least one of the foregoing photoresist materials, and the like.

The photoresist material can be deposited upon the semiconductor substrate 10 surface using conventional photomasking techniques involving particle removal, dehydration (e.g., dehydration baking), and priming (e.g., immersion priming, spin priming, vapor priming, and methods disclosed in U.S. Pat. No. 3,549,368 to Collins et al., and assigned to assignee), as well as photoresist spinning processes (e.g., static spin process, dynamic dispense process (including, moving-arm dispensing), manual and automatic spinners), backside coating processes (e.g., soft bake, hot plates such as manual, in-line single-wafer, moving-belt, moving belt infrared oven, microwave baking), and alignment and exposure processes (e.g., contact aligners, proximity aligners, scanning projection aligners, steppers, step and scan aligners, x-ray aligners, electron beam aligners, mix and match aligners, and any of the foregoing aligners coupled with a post exposure bake device), as well as combinations comprising at least one of the foregoing photomasking techniques, and the like.

In FIG. 3, the photoresist material layer 14 can be patterned using a mask or reticle pattern, and etched to form one or more device isolated regions 16 on the semiconductor substrate 10. Etching removes substrate material from the top layer(s) of the semiconductor substrate's surface through the openings in the resist pattern, i.e., mask or reticle, using either wet or dry chemical reactions, or by physical removal of the semiconductor substrate material. Possible etching methods can comprise wet etch techniques (e.g., wet spray etching, vapor etching) and dry etching techniques (e.g., plasma etching and planar plasma etching, ion beam etching, reactive ion etching (“RIE”)), as well as combinations comprising at least one of the foregoing etching methods, and the like. The choice of etchants is based upon physical properties including, but not limited to, good selectivity, i.e., their ability to uniformly remove the top layer(s) of the semiconductor substrate 10 without attacking the underlying material, and the like, as well as process factors such as incomplete etch, overetching, undercutting, selectivity, anisotropic/isotropic etching, and the like.

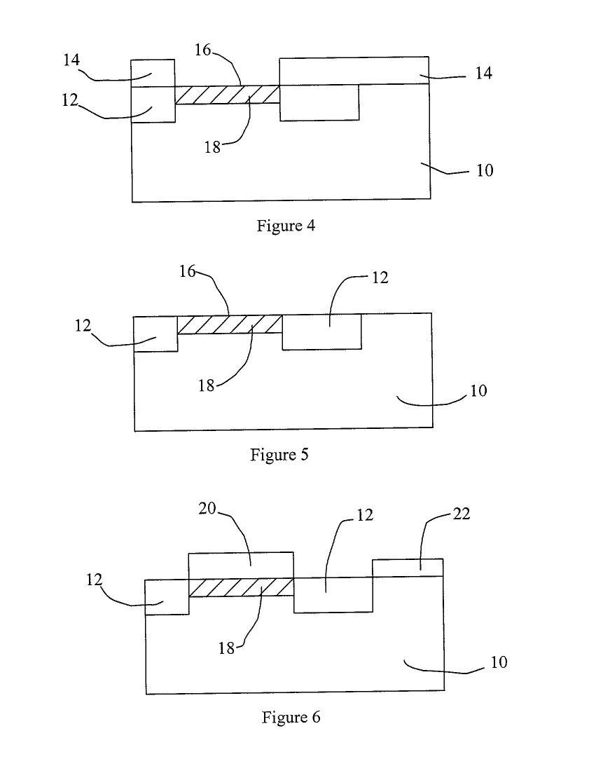

In FIG. 4, a layer or layers of porous silicon 18 can be deposited or formed on the semiconductor substrate 10. Possible methods for depositing or forming porous silicon layers 18 on the semiconductor substrate 10 can comprise electrolysis, epitaxial silicon processes employing silicon chemical sources such as silicon tetrachloride, silane, dichlorosilane, and the like, using chemical vapor deposition (“CVD”) techniques, as well as selective epitaxial silicon processes, and polysilicon and amorphous silicon deposition techniques, as well as combinations comprising at least one of the foregoing methods, and the like. Possible CVD systems can comprise atmospheric pressure chemical vapor deposition (“APCVD”) techniques such as horizontal tube-induction heated, barrel radiant-induction heated APCVD, pancake induction-heated APCVD, continuousconduction-heated APCVD, and horizontal-conduction-heated APCVD, and the like, or a low pressure chemical vapor deposition (“LPCVD”) technique such as horizontal conduction-convection-heated LPCVD, ultrahigh vacuum (“UHV/CVD”), and the like, or a plasma-enhanced chemical vapor deposition (“PECVD”) technique such as horizontal vertical flow PECVD, barrel radiant-heated PECVD, horizontal-tube PECVD, high density plasma (“HDPCVD”), and the like. When the silicon chemical source comprises a compound containing silicon, possible deposition processes can comprise epitaxy methods such as vapor phase epitaxy (“VPE”), molecular beam epitaxy (“MBE”), metal organic CVD (“MOCVD”), and the like. Likewise, possible processes for growing silicon can comprise electrolysis methods, as well as combinations comprising electrolysis methods, and the like.

More specifically, the layer of porous silicon 18 can be deposited or grown on the semiconductor substrate 10, and preferably the exposed silicon areas, by immersing the semiconductor substrate 10 in a solution comprising hydrogen fluoride (“HF”), an oxidant, and a solvent (e.g., alcohols, glycols, non-protic solvents, as well as combinations comprising at least one of the foregoing solvents, and the like). The solution comprises a ratio of components comprising 1:x:y, where x corresponds to the oxidant and is a value of about 1 to about 500, and y corresponds to the solvent and is a value of about 1 to about 500. While immersing the semiconductor substrate 10, a current of about 0.1 milliamperes per centimeters squared (“mA/cm ²”) to about 300 mA/cm² is passed through the solution. This process increases the differential oxidation rate of the exposed silicon area by converting the non-porous silicon to porous silicon. The porous silicon layer 18 forms within the device isolated regions 16 of the semiconductor substrate 10, while the photoresist material layers 14 block the porous silicon layer 18 from forming on other areas of the semiconductor substrate 10 surface.

In FIG. 5, the photoresist material layer 14 can be removed from the semiconductor substrate 10 using a resist stripping method. When stripping photoresist material from a semiconducting surface such as silicon, possible resist stripping methods can comprise wet chemical stripping methods such as phenolic organic strippers, solvent/amine strippers, specialty wet strippers, dry stripping, as well as combinations comprising at least one of the foregoing wet chemical stripping methods, and the like. When stripping photoresist material from a non-semiconducting surface, or an insulating surface, such as silicon dioxide, silicon nitride or polysilicon, possible resist stripping methods can comprise employing sulfuric acid and oxidant solutions, combinations comprising at least one of the foregoing materials, and the like. Once the resist mask is stripped away, the semiconductor substrate 10 is cleaned to remove resist contaminants. As illustrated in FIG. 5, once the photoresist material layer 14 is removed, the semiconductor substrate 10 comprises the trenches 12, exposed areas of non-porous silicon, and device isolated region 16 comprising porous silicon layers 18.

In FIG. 6, the semiconductor substrate 10 can be oxidized using several methods for depositing oxide materials, and/or forming oxide layer(s), i.e., gate oxides, upon semiconductor materials. Possible oxide materials can comprise SiO₂, Al₂0₃, HfO₂, TiO₂, as well as combinations comprising at least one of the foregoing oxides, and the like. In addition, the oxide material, or combination of oxide materials, employed can also correspond to the particular type of semiconductor substrate material. For example, when employing a silicon semiconductor substrate the corresponding oxide would most likely comprise SiO₂, or a combination comprising SiO₂. Possible methods for depositing the oxide, or forming the oxide layer(s), can comprise thermal oxidation techniques, CVD techniques as disclosed, and PECVD techniques as disclosed, atomic layer CVD techniques (“ALCVD”), and the like. Such methods can be applied to selectively oxidize porous silicon layers 18 at a temperature from about 750 degrees Celsius (“° C.”) to about 800° C. Two or more oxide layers, gate oxides, or multiple gate oxide thicknesses comprising variable oxide thicknesses can preferably form on the non-porous silicon areas and porous silicon layers 18 of the semiconductor substrate 10.

For example, a first oxide layer 20 having a thickness A can form on the porous silicon layer 18, while a second oxide layer 22 having a thickness B can form on the non-porous silicon areas of the semiconductor substrate 10. Since porous silicon possesses a higher differential oxidation rate and larger surface-to-volume ratio than non-porous silicon, the first oxide layer's thickness A is greater than the second oxide layer's thickness B. When the semiconductor substrate 10 is oxidized, the second oxide layer 22 forms on the surface of the non-porous silicon and does not diffuse into the non-porous silicon due to its small surface-to-volume ratio. In contrast, porous silicon possesses a surface-to-volume ratio of about 200 meters squared per cubic centimeter to about 1000 meters squared per cubic centimeter. When oxidized, the first oxide layer 20 diffuses into, and forms on and beneath the surface of porous silicon layer 18 due to porous silicon's large surface-to-volume ratio. As a result, when being oxidized, a greater amount of silicon dioxide, for example, will form on a porous silicon surface than a non-porous silicon surface. Accordingly, thickness A of the first oxide layer 20 will be greater than thickness B of the second oxide layer 22.

The method of forming variable oxide thicknesses across semiconductor substrates provides several advantages, such as lowering processing time and the cost savings associated therewith, over other methods. These other methods involve multiple oxidation steps as well as additional steps such as implanting nitrogen to reduce oxidation rates; implanting argon, oxygen, silicon, and/or fluorine, and the like, to enhance the oxidation rates; and, selectively doping specific areas of the semiconductor substrate, and the like, under varying process conditions, i.e., wet and dry oxygen, various temperature ranges, and the like. As a result, these other methods require multiple processing steps requiring additional time and labor, thus increasing the related manufacturing costs. In contrast, the method illustrated in FIGS. 1-6 can deposit two or more oxide layers comprising variable oxide thicknesses in a single step upon porous and non-porous silicon areas. As a result, the method requires less time to implement, less labor to achieve the desired results, and reduces costs.

All patents and references cited herein are fully incorporated by reference.

While preferred embodiments have been shown and described, various modifications and substitutions may be made thereto without departing from the spirit and scope of the invention. Accordingly, it is understood that the present invention has been described by way of illustrations and not limitation.

What is claimed:

1. A method of forming oxide layers of varying thicknesses across a semiconductor substrate surface, comprising:
patterning and blocking a semiconductor substrate surface with a layer of photoresist material;
removing a portion of the photoresist material layer to expose a device isolated region on a blocked semiconductor substrate surface;
increasing a differential oxidation rate value of an exposed semiconductor substrate surface;
removing the layer of photoresist material;
oxidizing the semiconductor substrate surface;
forming a first oxide layer having a first thickness on the exposed semiconductor substrate surface; and
forming a second oxide layer having a second thickness on the blocked semiconductor substrate surface, wherein the first thickness is greater than the second thickness.

2. The method of claim 1, wherein the increase in the differential oxidation rate value further comprises immersing the semiconductor substrate into a solution while passing a current of about 0.1 milliamps per centimeters squared to about 300 milliamps per centimeters squared.

3. The method of claim 2, wherein the solution comprises hydrogen fluoride, an oxidant and a solvent, wherein the solvent is selected from the group consisting of alcohols, glycols, non-protic solvents, and combinations comprising at least one of the foregoing solvents.

4. The method of claim 2, wherein the immersion further comprises converting an exposed semiconductor substrate material from a non-porous silicon material to a porous silicon material.

5. The method of claim 1, wherein the increase in the differential oxidation rate value further comprises converting an exposed semiconductor substrate material from a non-porous silicon material to a porous silicon material.

6. The method of claim 1, further comprising forming a shallow trench using shallow trench isolation.

7. The method of claim 6, further comprising filling the shallow trench to form a device isolation region.

8. The method of claim 1, wherein the removal of the portion of the photoresist layer further comprises etching the photoresist layer.

9. The method of claim 1, wherein the formation of the first oxide layer further comprises forming a first oxide layer on a porous silicon layer of the semiconductor substrate surface.

10. The method of claim 1, wherein the formation of the second oxide layer further comprises forming a second oxide layer on a non-porous silicon layer of the semiconductor substrate surface.

11. The method of claim 1, wherein the formation of the first oxide layer further comprises forming the first oxide layer having the first thickness on the exposed semiconductor surface by depositing an oxide material.

12. The method of claim 1, wherein the formation of the second oxide layer further comprises forming the second oxide layer having the second thickness on the blocked semiconductor substrate surface by depositing an oxide material.

13. The method of claim 1, wherein the formation of the first oxide layer further comprises forming the first oxide layer having the first thickness on the exposed semiconductor substrate by growing the first oxide layer.

14. The method of claim 1, wherein the formation of the second oxide layer further comprises forming the second oxide layer having the second thickness on the blocked semiconductor substrate surface by growing the second oxide layer.

15. A method for fabricating multiple gate oxide thicknesses across a semiconductor substrate surface, comprising:
photomasking a semiconductor substrate surface with a photoresist material;
etching a portion of the semiconductor substrate surface;
converting a non-porous semiconductor substrate material into a porous semiconductor substrate material;
stripping the photoresist material;
oxidizing the semiconductor substrate surface; and
forming two or more gate oxides, wherein a first gate oxide has a thickness greater than a second gate oxide thickness.

16. The method of claim 15, wherein the converting further comprises immersing the semiconductor substrate into a hydrogen fluoride electrolytic bath while passing a current of about 0.1 milliamps per centimeters squared to about 300 milliamps per centimeters squared through the bath.

17. The method of claim 15, wherein the forming further comprises forming the first gate oxide on a porous silicon layer of the semiconductor substrate surface.

18. The method of claim 15, wherein the forming further comprises forming a second gate oxide on a non-porous silicon layer of the semiconductor substrate surface.

19. A method of forming oxide layers of varying thicknesses across a semiconductor substrate surface, comprising:
photomasking a semiconductor substrate surface with a photoresist material;
etching a portion of the semiconductor substrate surface;
increasing a differential oxidation rate value of an etched portion of the semiconductor substrate surface;
stripping the photoresist material;
oxidizing the semiconductor substrate surface; and
growing two or more oxide layers, wherein a first oxide layer has a thickness greater than a second oxide layer thickness.

20. The method of claim 19, wherein the growth of the two or more oxide layers further comprises forming the first oxide layer on the etched portion of the semiconductor substrate surface.

21. The method of claim 19, wherein the growth of the two or more oxide layers further comprises forming a second oxide layer on a non-etched portion of the semiconductor substrate surface.
